(19) United States
(12) Patent Application Publication
(10) Pub. No.: US 2010/0237508 A1
(43) Pub. Date: Sep. 23, 2010

(54) POWER-SUPPLY WIRING STRUCTURE FOR MULTILAYER WIRING AND METHOD OF MANUFACTURING MULTILAYER WIRING

(75) Inventor: Tetsuaki Utsumi, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/721,734

(22) Filed: Mar. 11, 2010

(30) Foreign Application Priority Data
Mar. 17, 2009 (JP) 2009-064839

(51) Int. Cl. H01L 23/48; H01L 21/768

(52) U.S. Cl. 257/774; 438/637; 257/773; 257/E23.011; 257/E21.576

(57) ABSTRACT

A power-supply wiring structure for a multilayer wiring according to an embodiment of the present invention includes one intermediate wiring layer with a first direction set as a priority wiring direction including a position converting and connecting wire, which has crossing-position forming sections formed in crossing positions of upper-layer power supply wires and lower-layer power supply wires of the same kind and projecting sections projecting from the crossing-position forming sections to sides of upper-layer power supply wires of different kinds, and includes a wire connecting section that connects between the upper layer wires and the crossing-position forming section and connects between the projecting section and the lower layer wires via vias.

### CROSS-REFERENCE TO RELATED APPLICATIONS

This application is based upon and claims the benefit of priority from the prior Japanese Patent Application No. 2009-064839, filed on Mar. 17, 2009; the entire contents of which are incorporated herein by reference.

### BACKGROUND OF THE INVENTION

1. Field of the Invention

The present invention relates to a power-supply wiring structure for a multilayer wiring and a method of manufacturing the multilayer wiring.

2. Description of the Related Art

In general, in a semiconductor integrated circuit, in connecting between two power supply wires which are crossed each other and arranged at wiring layers separated in the vertical direction across intermediate wiring layers, a method of forming a connecting section by arranging, in a crossing area of the two power supply wires, stacked vias superimposed across connecting wires formed in the intermediate wiring layers to thereby connect between the two power supply wires is widely used. However, in such a method of connecting between power supply wires, the connecting wires occupy wiring tracks for signal wires in the intermediate wiring layers present between the two power supply wires. Therefore, a wiring property of the signal wires is deteriorated.

In the past, in one of the intermediate wiring layers of the connecting section, vias that connect among cross-shaped wires which are extending from a crossing section of the two power supply wires in respective wiring directions of the two power supply wires and upper and lower wiring layers thereof are respectively arranged along a priority wiring direction of the wiring layers at connection destinations (see, for example, Japanese Patent Application Laid-Open No. 2008-66371). Consequently, even when the number of vias is the same, the number of wiring tracks occupied by the connecting wires in the upper and lower wiring layers is reduced.

However, in the method disclosed in Japanese Patent Application Laid-Open No. 2008-66371, the cross-shaped wires also have extending sections in a non-priority wiring direction of the wires. Therefore, the number of wiring tracks occupied by the cross-shaped wires increases in the intermediate wiring layer.

### BRIEF SUMMARY OF THE INVENTION

A power-supply wiring structure for a multilayer wiring according to an embodiment of the present invention comprises: a lower-layer power-supply wiring layer including a plurality of sets of two lower-layer power supply wires of different kinds extending in a first direction; an upper-layer power-supply wiring layer formed in a layer above the lower-layer power-supply wiring layer and including a plurality of sets of two upper-layer power supply wires of different kinds extending in a second direction; one or more intermediate wiring layers with the first direction set as a priority wiring direction and one or more intermediate wiring layers with the second direction set as a priority wiring direction, the intermediate wiring layers being formed between the lower-layer power-supply wiring layer and the upper-layer power-supply wiring layer; insulating films formed among the wiring layers; and a wiring connecting section that connects the lower-layer power supply wires and the upper-layer power supply wires of the same kind via connecting wires formed in the intermediate wiring layers and vias formed to pierce through the insulating films, wherein one intermediate wiring layer with the first direction set as the priority wiring direction among the intermediate wiring layers includes, as the connecting wires, position converting wires including crossing-position forming sections formed in crossing positions of the upper-layer power supply wires and the lower-layer power supply wires of the same kind and projecting sections projecting from the crossing-position forming sections to sides of the upper-layer power supply wires of the different kinds in the first direction, and the wire connecting section connects between the upper-layer power supply wires and the crossing-position forming sections of the position converting wires and connects between the projecting sections of the position converting wires and the lower-layer power supply wires via the vias.

A power-supply wiring structure for a multilayer wiring according to an embodiment of the present invention comprises: a lower-layer power-supply wiring layer including a plurality of sets of two lower-layer power supply wires of different kinds extending in a first direction; an upper-layer power-supply wiring layer formed in a layer above the lower-layer power-supply wiring layer and including a plurality of sets of two upper-layer power supply wires of different kinds extending in a second direction; one or more intermediate wiring layers with the first direction set as a priority wiring direction and one or more intermediate wiring layers with the second direction set as a priority wiring direction, the intermediate wiring layers being formed between the lower-layer power-supply wiring layer and the upper-layer power-supply wiring layer; insulating films formed among the wiring layers; and a wiring connecting section that connects the lower-layer power supply wires and the upper-layer power supply wires of the same kind via connecting wires formed in the intermediate wiring layers and vias formed to pierce through the insulating films, wherein one intermediate wiring layer with the first direction set as the priority wiring direction among the intermediate wiring layers includes, as the connecting wires, in the wire connecting section of one kind of two kinds of the wire connecting sections, position converting wires including crossing-position forming sections formed in crossing positions of the upper-layer power supply wires and the lower-layer power supply wires of the same kind and projecting sections projecting from the crossing-position forming sections to below the upper-layer power supply wires of the different kinds in the first direction, the wire connecting section of the one kind connects between the upper layer wires and the crossing-position forming sections of the position converting wires and connects between the projecting sections of the position converting wires and the lower layer wires via the vias, and the wiring connecting section of the other kind connects between the upper layer wires and the lower layer wires via the vias.

A method of manufacturing a multilayer wiring according to an embodiment of the present invention comprises a lower-layer power-supply wiring layer including a plurality of sets of two lower-layer power supply wires of different kinds extending in a first direction; an upper-layer power-supply wiring layer formed in a layer above the lower-layer power-supply wiring layer and including a plurality of sets of two upper-layer power supply wires of different kinds extending in a second direction; one or more intermediate wiring layers with the first direction set as a priority wiring direction and one or more intermediate wiring layers with the second direction set as a priority wiring direction, the intermediate wiring layers being formed between the lower-layer power-supply wiring layer and the upper-layer power-supply wiring layer; insulating films formed among the wiring layers; and a wiring connecting section that connects between the lower-layer power supply wires and the upper-layer power supply wires of the same kind via connecting wires formed in the intermediate wiring layers and vias formed to pierce through the insulating films, the method comprising: forming a conductive material film on the insulating film, etching the conductive material film, and forming, in one of the intermediate wiring layers with the first direction set as the priority wiring direction, as the connecting wire, a position converting wire extending in the first direction that connects between a crossing position of the lower-layer power supply wire and the upper-layer power supply wire to be formed later of a same kind and a predetermined position from the crossing position to forming positions of the upper-layer power supply wires of the different kinds; forming, in the intermediate wiring layers below the intermediate wiring layer including the position converting wire, connecting wires in crossing positions of the lower-layer power supply wires and the position converting wire; forming, in the insulating films below the intermediate wiring layer including the position converting wire, vias in crossing positions of the lower-layer power supply wires and the position converting wire; forming, in the intermediate wiring layers above the intermediate wiring layer including the position converting wire, connecting wires in crossing positions of the upper-layer power supply wires and the position converting wire; and forming, in the insulating films above the intermediate wiring layer including the position converting wire, vias in crossing positions of the upper-layer power supply wires and the position converting wire.

### BRIEF DESCRIPTION OF THE DRAWINGS

FIG. 1 is a schematic perspective view of an example of a power-supply wiring structure for a multilayer wiring in a semiconductor integrated circuit according to an embodiment of the present invention;

FIG. 2 is a plan view of a lower-layer power-supply wiring layer shown in FIG. 1;

FIG. 3 is a plan view of a first intermediate wiring layer shown in FIG. 1;

FIG. 4 is a plan view of a second intermediate wiring layer shown in FIG. 1;

FIG. 5 is a plan view of an upper-layer power-supply wiring layer shown in FIG. 1;

FIG. 6 is a sectional view of the upper-layer power-supply wiring layer taken along line A-A shown in FIG. 5;

FIG. 7 is a sectional view of the upper-layer power-supply wiring layer taken along line B-B shown in FIG. 5;

FIGS. 8A to 8K are schematic sectional views of an example of a procedure of a method of manufacturing the power-supply wiring structure for the multilayer wiring according to the embodiment;

FIGS. 9A to 9K are schematic sectional views of an example of a procedure of a method of manufacturing the power-supply wiring structure for the multilayer wiring according to the embodiment;

FIGS. 10A and 10B are sectional view of the upper-layer power-supply wiring layer of another embodiment;

FIG. 11 is a perspective view of an example of a general power-supply wiring structure;

FIG. 12 is a plan view of an upper-layer power-supply wiring layer shown in FIG. 11;

FIG. 13 is a plan view of a first intermediate wiring layer; and

FIG. 14 is a diagram of an example of the configuration of a standard cell.

### DETAILED DESCRIPTION OF THE INVENTION

Exemplary embodiments of the present invention are explained in detail below with reference to the accompanying drawings. In the embodiments, a power-supply wiring structure in a multilayer wiring structure of a semiconductor integrated circuit is explained as an example. However, the present invention is not limited by the embodiments. Perspective views and sectional views of the multilayer wiring of the semiconductor integrated circuit used in the embodiments are schematic. A relation between the thickness and the width of a layer, a ratio of the thicknesses of layers, and the like are different from actual ones.

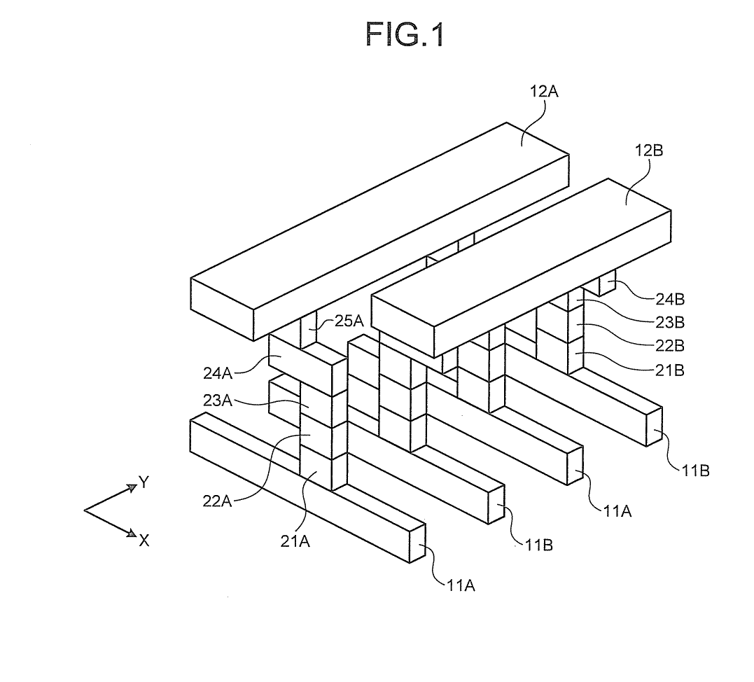

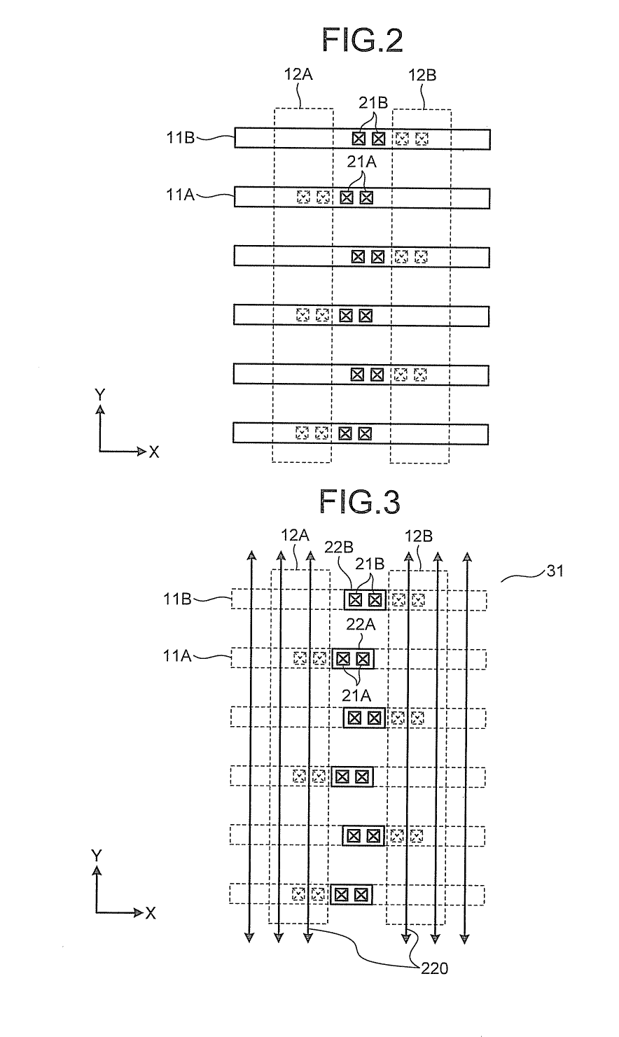

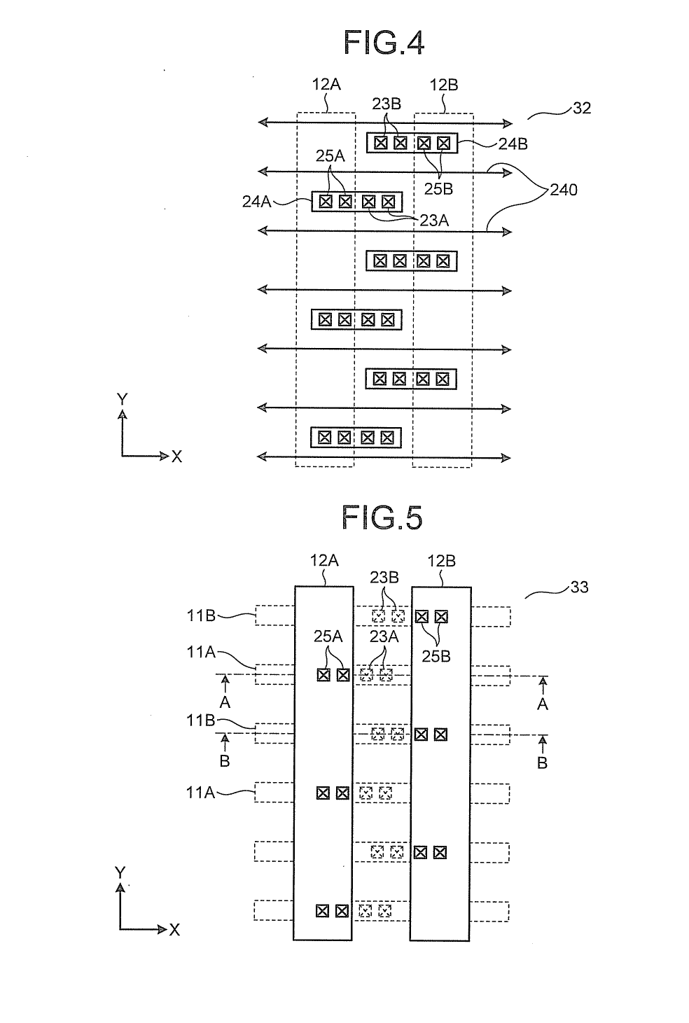

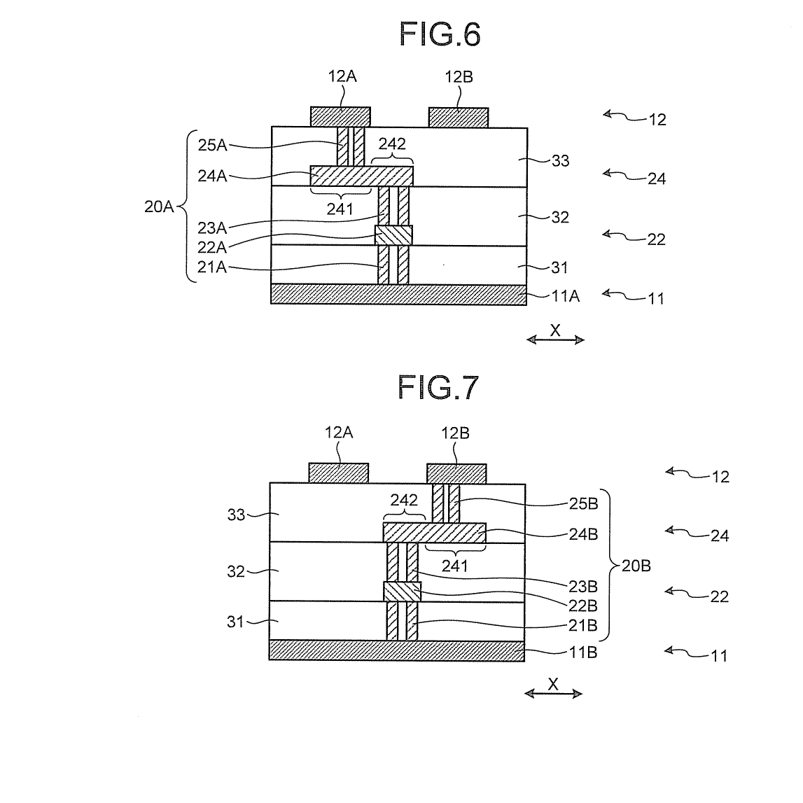

FIG. 1 is a schematic perspective view of an example of a power-supply wiring structure for a multilayer wiring in a semiconductor integrated circuit according to an embodiment of the present invention. FIG. 2 is a plan view of a lower-layer power-supply wiring layer shown in FIG. 1. FIG. 3 is a plan view of a first intermediate wiring layer shown in FIG. 1. FIG. 4 is a plan view of a second intermediate wiring layer shown in FIG. 1. FIG. 5 is a plan view of an upper-layer power-supply wiring layer shown in FIG. 1. FIG. 6 is a sectional view of the upper-layer power-supply wiring layer taken along line A-A shown in FIG. 5. FIG. 7 is a sectional view of the upper-layer power-supply wiring layer taken along line B-B shown in FIG. 5.

The power-supply wiring structure in the semiconductor integrated circuit has a structure having laminated therein in order a lower-layer power-supply wiring layer 11 in which lower-layer power supply wires (first power supply wires 11A and second power supply wires 11B) are formed, a first interlayer insulating film 31, a first intermediate wiring layer 22 in which signal wires and the like are formed, a second interlayer insulating film 32, a second intermediate wiring layer 24 in which signal wires and the like are formed, a third interlayer insulating film 33, and an upper-layer power-supply wiring layer 12 in which upper-layer power supply wires (a first power supply wire 12A and a second power supply wire 12B) are formed. A forming direction (an extending direction) of the lower-layer power supply wires (the first power supply wires 11A and the second power supply wires 11B) is represented as X direction. A forming direction (an extending direction) of the upper-layer power supply wires (the first power supply wire 12A and the second power supply wire 12B) is represented as Y direction.

In the lower-layer power-supply wiring layer 11, as shown in FIGS. 1, 2, 6, and 7, the first power supply wires 11A and the second power supply wires 11B extending in the X direction are alternately formed in the Y direction at predetermined intervals. The first interlayer insulating film 31 is formed on the lower-layer power-supply wiring layer 11.

As shown in FIGS. 1, 3, 6, and 7, the first intermediate wiring layer 22 is formed on the first interlayer insulating film 31. In the first intermediate wiring layer 22, not-shown intermediate wires such as signal wires are formed to extend in the Y direction as a priority wiring direction. Arrows extending in the Y axis direction in FIG. 3 indicate wiring tracks 220 in which the signal wires can be arranged. In the first intermediate wiring layer 22, connecting wires 22A and 22B forming wire connecting sections 20A and 20B explained later are also formed. The second interlayer insulating film 32 is formed on the first intermediate wiring layer 22.

As shown in FIGS. 1, 4, 6, and 7, the second intermediate wiring layer 24 is formed on the second interlayer insulating film 32. In the second intermediate wiring layer 24, not-shown intermediate wires such as signal wires are formed to extend in the X direction as a priority wiring direction. Arrows extending in the X axis direction in FIG. 4 indicate wiring tracks 240 in which the signal wires can be arranged. In the second intermediate wiring layer 24, connecting wires 24A and 24B forming the wire connecting sections 20A and 20B are also formed. The third interlayer insulating film 33 is formed on the second intermediate wiring layer 24.

As shown in FIGS. 1 and 5 to 7, the upper-layer power-supply wiring layer 12 is formed on the third interlayer insulating film 33. In the upper-layer power-supply wiring layer 12, the first power supply wire 12A and the second power supply wire 12B extending Y direction are alternately formed in the X direction at predetermined intervals. In this wiring structure, the first power supply wires 11A and 12A are power supply wires of the same kind, for example, VDD wires used for supplying power supply potential (VDD). The second power supply wires 11B and 12B are power supply wires of the same kind, for example, VSS wires used for supplying ground potential (VSS).

The first power supply wires 11A and 12A of the lower-layer power-supply wiring layer 11 and the upper-layer power-supply wiring layer 12 are electrically connected via the wire connecting section 20A including the connecting wires 22A and 24A formed in the first and second intermediate wiring layers 22 and 24 and first vias 21A, 23A, and 25A formed in the first to third interlayer insulating films 31 to 33. Similarly, the second power supply wires 11B and 12B of the lower-layer power-supply wiring layer 11 and the upper-layer power-supply wiring layer 12 are electrically connected via the wire connecting section 23B including the connecting wires 22B and 24B formed in the first and second intermediate wiring layers 22 and 24 and vias 21B, 23B, and 25B formed in the first to third interlayer insulating films 31 to 33.

In this embodiment, in the first intermediate wiring layer 22 wired in the priority wiring direction (the Y direction) same as that of the upper-layer power-supply wiring layer 12, forming positions of the first vias 21A and 23A connected to the connecting wire 22A and forming positions of the second vias 21B and 23B connected to the connecting wire 22B are substantially linearly arranged in an area between the first power supply wire 12A and the second power supply wire 12B of the upper-layer power-supply wiring layer 12. Consequently, the connecting wires 22A and 22B are also substantially linearly arranged between the first power supply wire 12A and the second power supply wire 12B.

Specifically, first vias that connect between the upper and lower first power supply wires 11A and 12A include the vias 21A, 23A, and 25A formed to pierce through in the thickness direction in the first to third interlayer insulating films 31 to 33 and the connecting wires 22A and 24A that connect among the upper and lower vias 21A, 23A, and 25A in the first and second intermediate wiring layers 22 and 24. The connecting wire 24A formed in the second intermediate wiring layer 24 having a priority wiring direction different from that of the upper-layer power-supply wiring layer 12 includes a wire extending in the X direction including a crossing-position forming section 241 and a projecting section 242. The crossing-position forming section 241 is formed in a crossing area of the first power supply wire 12A of the upper-layer power-supply wiring layer 12 and the first power supply wires 11A of the lower-layer power-supply wiring layer 11. The projecting section 242 is formed to project from the crossing-position forming section 241 in the direction of the second power supply wire 12B of the upper-layer power-supply wiring layer 12. The connecting wire 24A including the crossing-position forming section 241 and the projecting section 242 is referred to as via-position converting and connecting wire 24A below. Specifically, the via-position converting and connecting wire 24A is formed longer than the length in the X direction of the connecting wire 22A formed in the first intermediate wiring layer 22 to change positions in the X direction of the vias 25A and 23A. The projecting section 242 of the via-position converting and connecting wire 24A and the first power supply wires 11A of the lower-layer power-supply wiring layer 11 are substantially vertically connected via the vias 21A and 23A and the connecting wire 22A. Consequently, at least a part of the vias 21A and 23A and the connecting wire 22A present in a layer below the via-position converting and connecting wire 24A is formed to extend beyond the crossing area of the upper and lower power supply wires 11A and 12A.

Similarly, second vias that connect between the upper and lower second power supply wires 11B and 12B include the vias 21B, 23B, and 25B formed to pierce through in the thickness direction in the first to third interlayer insulating films 31 to 33 and the connecting wires 22B and 24B that connect among the upper and lower vias 21B, 23B, and 25B in the first and second intermediate wiring layers 22 and 24. The connecting wire 24B formed in the second intermediate wiring layer 24 includes a wire extending in the X direction including the crossing-position forming section 241 formed in a crossing area of the upper and lower second power supply wires 11B and 12B and the projecting section 242 formed to project from the crossing-position forming section 241 in the direction of the first power supply wire 12A of the upper-layer power-supply wiring layer 12. The connecting wire 24B including the crossing-position forming section 241 and the projecting section 242 is referred to as via-position converting and connecting wire 24B below. Specifically, the via-position converting and connecting wire 24B is formed longer than the length in the X direction of the connecting wire 22B formed in the first intermediate wiring layer 22 to change positions in the X direction of the vias 25B and 23B. The projecting section 242 of the via-position converting and connecting wire 24B and the second power supply wires 11B of the lower-layer power-supply wiring layer 11 are substantially vertically connected via the vias 21B and 23B. Consequently, at least a part of the vias 21B and 23B and the connecting wire 22B present in a layer below the via-position converting and connecting wire 24B is formed to extend beyond the crossing area of the upper and lower power supply wires 11B and 12B.

When the wire connecting sections 20A and 20B are formed in this way, the forming positions of the vias 21A and 23A and the connecting wire 22A and the forming positions of the second vias 21B and 23B and the connecting wire 22B of the first intermediate wiring layer 22 are substantially linearly formed in an area between the first power supply wire 12A and the second power supply wire 12B in the upper-layer power-supply wiring layer 12.

In the example explained above, the position in the X direction of the connecting wire 22A in the wire connecting section 20A that connects between the first power supply wires 11A and 12A and the position in the X direction of the connecting wire 22B in the wire connecting section 20B that connects between the second power supply wires 11B and 12B generally overlap. The connecting wire 22A and the connecting wire 22B are linearly formed. However, this does not mean that the present invention is limited to this. At least a part of the connecting wire 22A only has to be formed to project from the crossing area of the upper and lower first power supply wires 11A and 12A to the second power supply wire 12B side. A part of the connecting wire 22B only has to be formed to project from the crossing area of the upper and lower second power supply wires 11B and 12B to the first power supply wire 12A side. In other words, the connecting wire 22A and the connecting wire 22B only have to be formed such that the positions in the X direction thereof partially overlap.

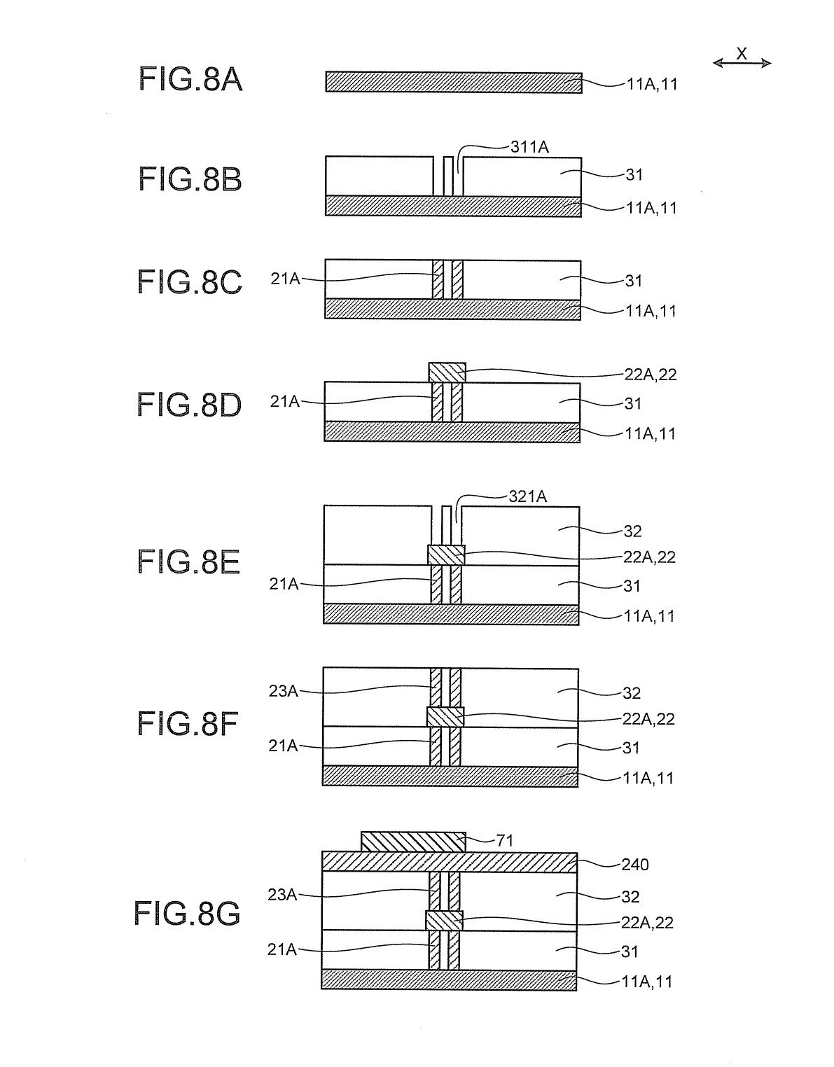

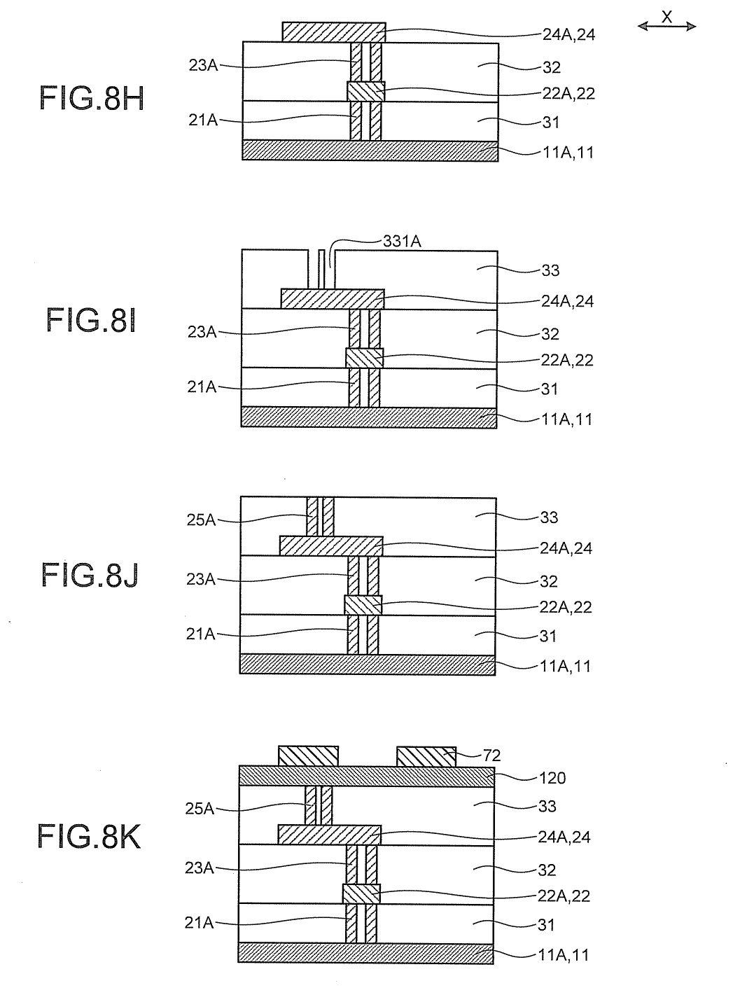

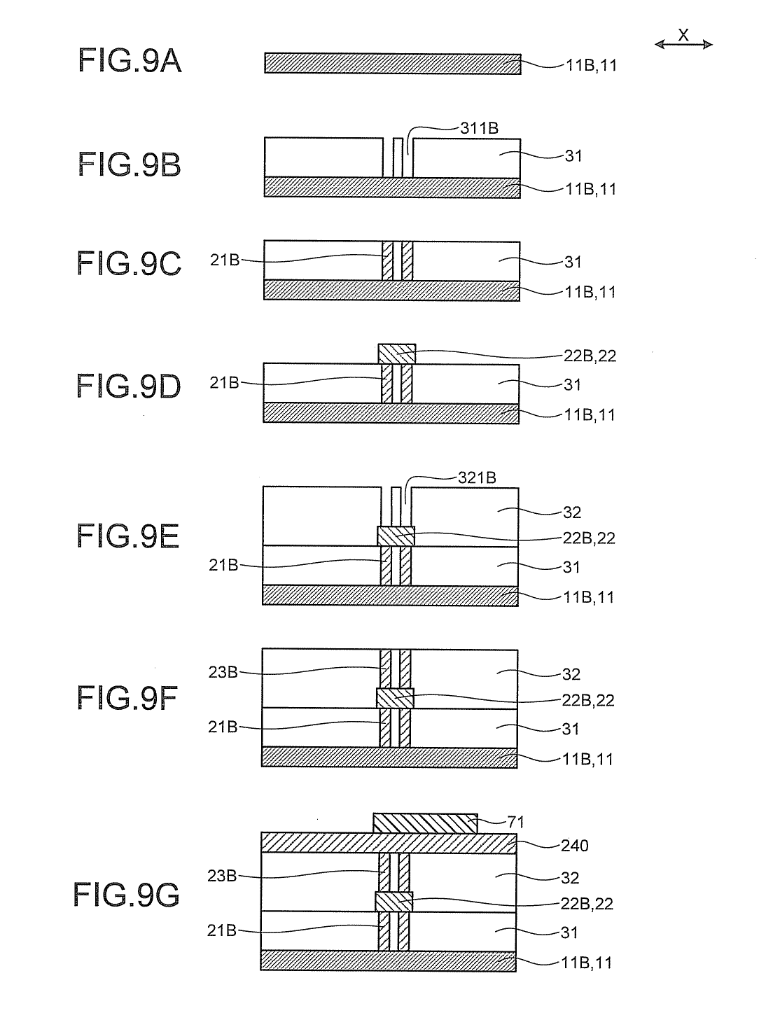

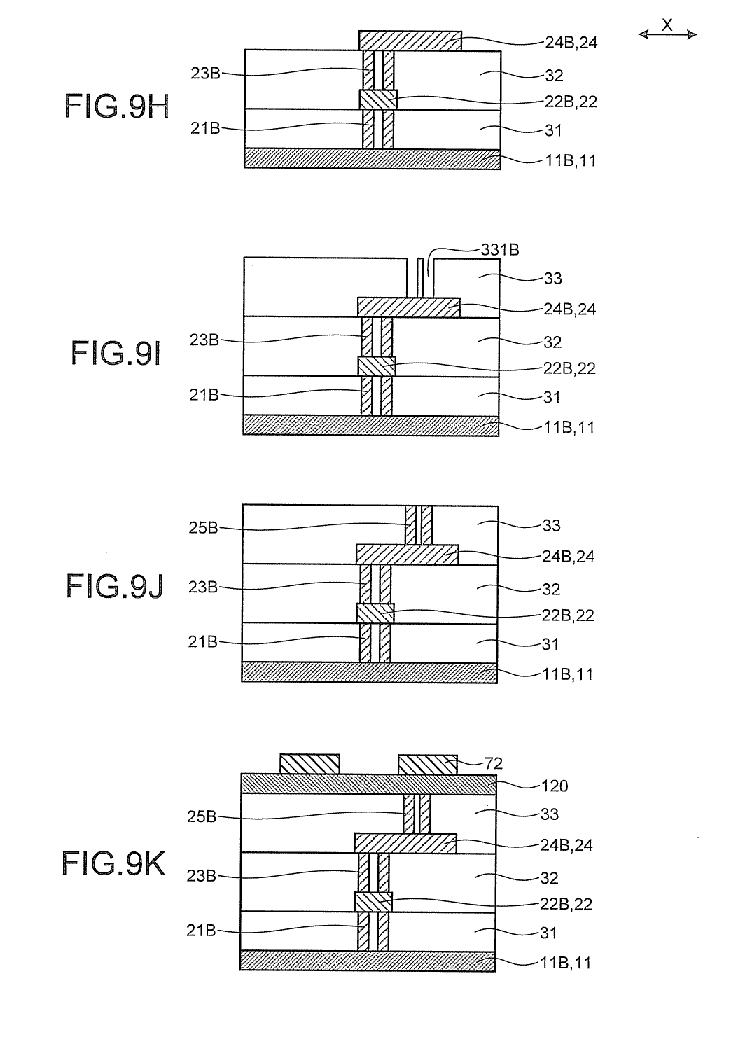

FIGS. 8A to 9K are schematic sectional views of an example of a procedure of a method of manufacturing the power-supply wiring structure for the multilayer wiring according to this embodiment. FIGS. 8A to 8K are sectional views of a section corresponding to an A-A section shown in FIG. 5. FIGS. 9A to 9K are sectional views of a section corresponding to a B-B section shown in FIG. 5.

First, a not-shown insulating film as an interlayer insulating film is formed on a substrate (not shown in the figure) such as a semiconductor substrate in which an element such as a field effect transistor is formed. The lower-layer power-supply wiring layer 11 including the first power supply wires 11A and the second power supply wires 11B is formed. As shown in FIG. 1, the first power supply wires 11A and the second power supply wires 11B are formed to extend in the X direction and to be alternately repeatedly arranged in the Y direction at predetermined intervals (FIGS. 8A and 9A).

Subsequently, the first interlayer insulting film 31 such as a silicon oxide film is formed on the insulating film on which the first and second power supply wires 11A and 11B are formed. A resist is applied on the first interlayer insulating film 31. A resist pattern in which the surface of the first interlayer insulating film 31 is exposed in via forming positions is formed by a lithography technique. With the resist pattern as a mask, via holes 311A and 311B piercing through the first interlayer insulating film 31 are formed by anisotropic etching such as the reactive ion etching (RIE) method (FIGS. 8B and 9B). The via holes 311A and 311B are formed on the forming positions of the first power supply wires 11A and the second power supply wires 11B. Forming positions in the X direction of the via holes 311A and 311B are present between the forming position of the first power supply wire 12A and the forming position of the second power supply wire 12B of the upper-layer power-supply wiring layer 12 to be formed later. However, it is assumed that positions in the X direction of the via hole 311A formed on the first power supply wire 11A and the via hole 311B formed on the second power supply wire 11B generally coincide with each other.

Thereafter, a conductive material film of W, Al, or the like is formed in the via holes 311A and 311B and on the first interlayer insulating film 31 by a film forming method with high step covering properties such as the sputtering method or the plasma chemical vapor deposition (CVD) method. The conductive material film is removed by the chemical mechanical polishing (CMP) method until the surface of the first interlayer insulating film 31 is exposed. The vias 21A and 21B are formed in the via holes 311A and 311B. Alternatively, it is also possible that, after a barrier metal film is formed to coat the sides and the bottoms of the via holes 311A and 311B, the via holes 311A and 311B coated with the barrier metal film are filled with the conductive material film of W, Al, or the like. Consequently, the via 21A is formed in the via hole 311A on the first power supply wire 11A and the via 21B is formed in the via hole 311B on the second power supply wire 11B (FIGS. 8C and 9C).

The conductive material film of W, Al, or the like is formed over the entire surface on the first interlayer insulating film 31 in which the vias 21A and 21B are formed by a method such as the sputtering method or the CVD method. A resist is applied on the upper surface of the conductive material film. Thereafter, a resist pattern is formed by the lithography technique to expose an area other than positions where a wiring pattern other than the power supply wires extending in the Y direction is formed and the connecting wires of the wire connecting sections 20A that connects between the upper and lower first power supply wires 11A and 12A, and the wire connecting sections 20B that connects between the upper and lower second power supply wires 11B and 12B are formed. The conductive material film is etched by using the resist pattern to form the first intermediate wiring layer 22 (FIGS. 8D and 9D). As the first intermediate wiring layer 22, only the connecting wires 22A and 22B are shown in the figures. As shown in FIG. 3, a forming position in the X direction of the connecting wire 22A connected to the first power supply wires 11A and a forming position in the X direction of the connecting wire 22B connected to the second power supply wires 11B generally coincide with each other like the positions of the vias 21A and 21B. The connecting wires 22A and 22B connect between the upper and lower vias. Therefore, the width of the wires (the length in a non-priority wiring direction) is equivalent to the width of other wires such as not-shown signal wires.

The second interlayer insulating film 32 made of a silicon oxide film or the like is formed on the first interlayer insulating layer 31 on which the first intermediate wiring layer 22 is formed. A resist is applied on the second interlayer insulating film 32 and a resist pattern in which the surface of the second interlayer insulating film 32 is exposed in via forming positions is formed by the lithography technique. With the resist pattern as a mask, via holes 321A and 321B piercing through the second interlayer insulating film 32 are formed by anisotropic etching such as the RIE method (FIGS. 8E and 9E). The via holes 321A and 321B are formed on the connecting wires 22A and 22B formed in the first intermediate wiring layer 22 and formed in substantially the same positions as the via holes 311A and 311B formed in the first interlayer insulating film 31.

Thereafter, according to a procedure same as the procedure for forming the vias 21A and 21B, the conductive material film is filled in the via holes 311A and 311B, the via 23A is formed in the via hole 321A on the connecting wire 22A, and the via 23B is formed in the via hole 321B on the connecting wire 22B (FIGS. 8F and 9F).

A conductive material film 240 of W, Al, or the like is formed over the entire surface on the second interlayer insulating film 32, in which the vias 23A and 23B are formed, by a method such as the sputtering method or the CVD method and a resist is applied on the upper surface of the conductive material film 240. Thereafter, a resist pattern 71 is formed by the lithography technique to expose an area other than positions where a wiring pattern other than the power supply wires extending in the X direction is formed and the connecting wires of the wire connecting sections 20A that connects between the upper and lower first power supply wires 11A and 12A, and the wire connecting sections 20B that connects between the upper and lower second power supply wires 11B and 12B are formed (FIGS. 8G and 9G). The resist pattern 71 is a pattern extending in the X direction that connects between the forming positions of the vias 23A and 23B and crossing positions of the upper and lower power supply wires of the same kind.

With the resist pattern 71 as a mask, the conductive material film 240 is etched to form the second intermediate wiring layer 24 having the via-position converting and connecting wires 24A and 24B (FIGS. 8H and 9H). The via-position converting and connecting wire 24A is a pattern extending in the X direction including the crossing-position forming section 241 formed in a crossing position of the upper and lower first power supply wires 11A and 12A and the projecting section 242 extending in the X direction from the crossing-position forming section 241 to above the forming position of the via 23A. Similarly, the via-position converting and connecting wire 24B is a pattern extending in the X direction including the crossing-position forming section 241 formed in a crossing position of the upper and lower second power supply wires 11B and 12B and the projecting section 242 extending in the X direction from the crossing-position forming section 241 to above the forming position of the via 23B. As shown in FIG. 4, the forming positions in the X direction of the projecting sections 242 of the two kinds of via-position converting and connecting wires 24A and 24B overlap each other.

Thereafter, the third interlayer insulating film 33 made of a silicon oxide film is formed on the second interlayer insulating film 32 on which the second intermediate wiring layer 24 is formed. A resist is applied on the third interlayer insulating film 33 and a resist pattern in which the surface of the third interlayer insulating film 33 is exposed in via forming positions is formed by the lithography technique. The via forming positions are the crossing-position forming sections 241 of the via-position converting and connecting wires of the second intermediate wiring layer 24, i.e., crossing positions of the lower-layer power supply wires of the same kind and upper-layer power supply wires to be formed later. With the resist pattern as a mask, via holes 331A and 331B piercing through the third interlayer insulating film 33 are formed by anisotropic etching such as the RIE method (FIGS. 8I and 9I). As explained above, the via holes 331A and 331B are formed on the crossing-position forming sections 241 of the via-position converting and connecting wires 24A and 24B.

According to a procedure same as the procedure for forming the vias 21A and 21B, the conductive material film is embedded in the via holes 331A and 331B, the via 25A is formed in the via hole 331A on the via-position converting and connecting wire 24A, and the via 25B is formed in the via hole 331B on the via-position converting and connecting wire 24B (FIGS. 8J and 9J).

Thereafter, a conductive material film 120 of W, Al, or the like is formed over the entire surface on the third interlayer insulating film 33, in which the vias 25A and 25B are formed, by a method such as the sputtering method or the CVD method and a resist is applied on the upper surface of the conductive material film 120. Thereafter, a resist pattern 72 is formed by the lithography technique to expose an area other than a position where a wiring pattern other than the power supply wires extending in the Y direction is formed (FIGS. 8K and 9K). With the resist pattern 72 as a mask, the conductive material film 120 is etched to form the upper-layer power-supply wiring layer 12 including the first and second power supply wires 12A and 12B. As shown in FIG. 5, the first power supply wire 12A and the second power supply wire 12B are formed to extend in the Y direction and to be alternately repeatedly arranged at predetermined intervals. Consequently, the power-supply wiring structure for the multilayer wiring having the structure shown in FIG. 1 is obtained.

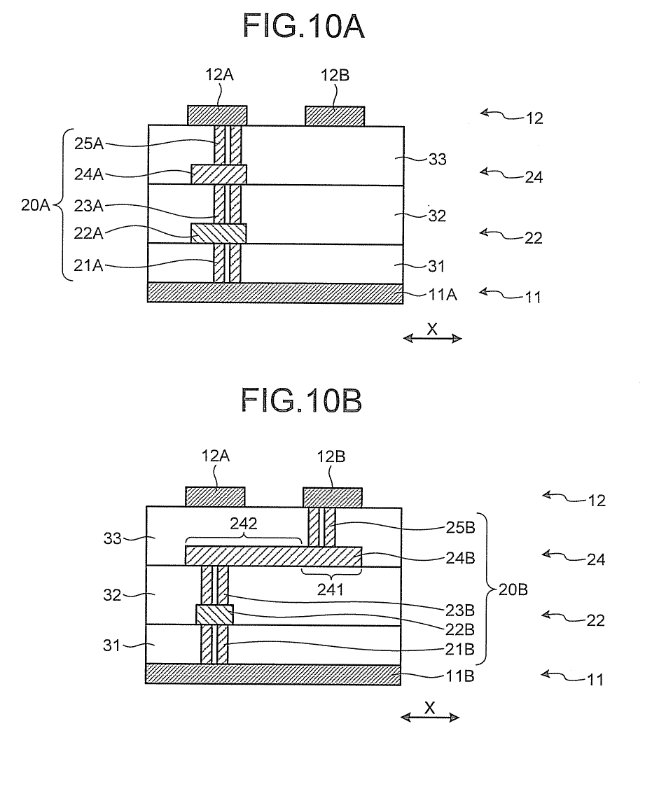

In the above explanation, the wire connecting section 20A that connects between the first power supply wires 11A and 12A and the wire connecting section 20B that connects between the second power supply wires 11B and 12B respectively include the via-position converting and connecting wires 24A and 24B. And at least a part of the forming positions of the vias 21A and 23A and the connecting wire 22A and the forming positions of the vias 21B and 23B and the connecting wire 22B below the via-position converting and connecting wires 24A and 24B overlap between the first power supply wire 12A and the second power supply wire 12B in the upper-layer power-supply wiring layer 12. However, it is also that a via-position converting and connecting wire is not provided in a wire connecting section that connects between one upper and lower power supply wires and a via-position converting and connecting wire is provided only in a wire connecting section that connects between the other upper and lower power supply wires. FIGS. 10A and 10B are sectional view of the upper-layer power-supply wiring layer of another embodiment. For example, as shown in FIGS. 10A and 10B, the wire connecting section 20A that connects between the first power supply wires 11A and 12A is provided substantially vertically in the crossing positions of the upper and lower first power supply wires 11A and 12A. The via-position converting and connecting wire 24B of the wire connecting section 20B that connects between the second power supply wires 11B and 12B is formed such that the projecting section 242 is extended to the forming position of the first power supply wire 12A of the upper-layer power-supply wiring layer 12. The via-position converting and connecting wire 24B is connected to the first power supply wires 11A of the lower-layer power-supply wiring layer 11 near the forming position of the first power supply wire 12A of the projecting section 242. In such structure, the first and second power supply wires can be interchanged.

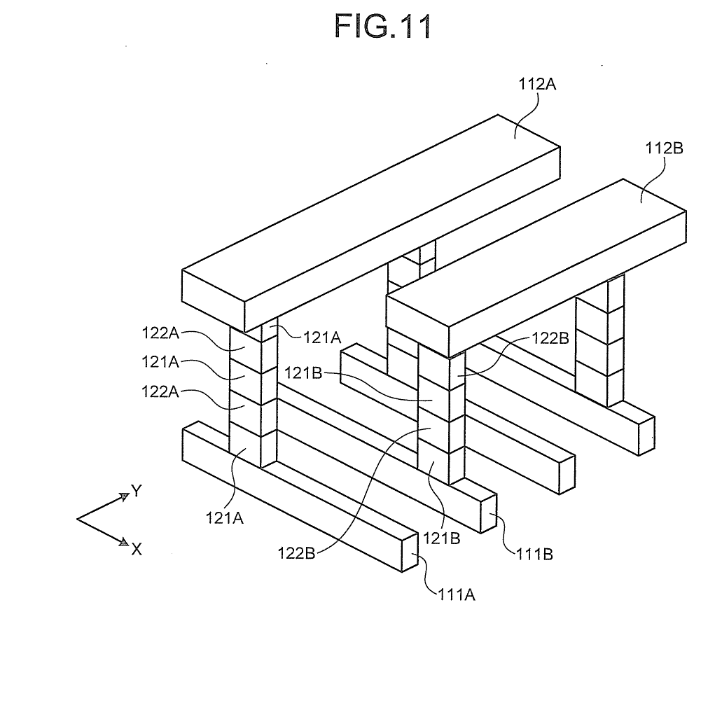

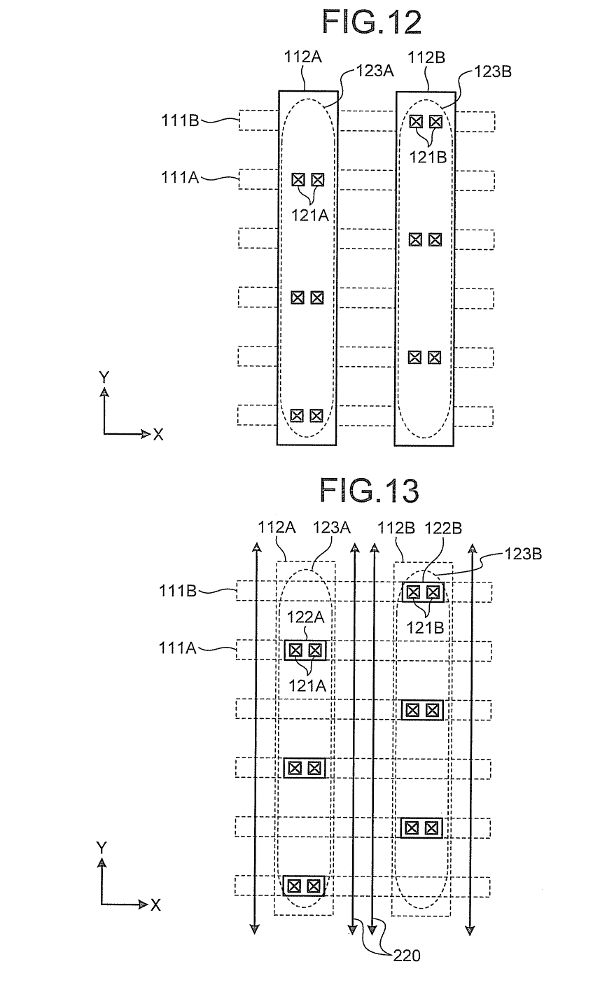

FIG. 11 is a perspective view of an example of a general power-supply wiring structure. FIG. 12 is a plan view of an upper-layer power-supply wiring layer shown in FIG. 11. FIG. 13 is a plan view of a first intermediate wiring layer. As shown in the figures, stacked vias are formed in crossing positions of an upper-layer power supply wire and a lower-layer power supply wire to connect between the upper-layer power supply wire and the lower-layer power supply wire. Specifically, first vias 121A and connecting wires 122A that connect between upper and lower first power supply wires 111A and 112A are laminated and formed substantially vertically in positions corresponding to crossing positions of the first power supply wires 111A of a lower-layer power-supply wiring layer and the first power supply wire 112A of an upper-layer power-supply wiring layer. Second vias 121B and connecting wires 122B that connect between upper and lower second power supply wires 111B and 112B are laminated and formed substantially vertically in positions corresponding to crossing positions of the second power supply wires 111B of the lower-layer power-supply wiring layer and the second power supply wire 112B of the upper-layer power-supply wiring layer.

Consequently, as shown in FIGS. 12 and 13, the positions of the first vias 121A (the connecting wires 122A) and the second vias 121B (the connecting wires 122B) are arranged in a zigzag shape. Specifically, in the power-supply wiring structure, via rows 123A and 123B are formed in a number same as the number of the first and second power supply wires 112A and 112B formed in the upper-layer power-supply wiring layer. As a result, as shown in FIG. 13, the wiring tracks 220 are arranged in the Y direction in the first intermediate wiring layer having the priority wiring direction (the Y direction) same as that of the upper-layer power-supply wiring layer. However, the wiring tracks 220 cannot be arranged in areas where the via rows 123A and 123B formed by the first vias 121A and the second vias 121B are formed.

On the other hand, in the embodiment explained above, the positions of the first vias 21A and 23A that connect between the upper and lower first power supply wires 11A and 12A and the positions of the second vias 21B and 23B that connect between the upper and lower second power supply wires 11B and 12B are arranged in the area between the first power supply wire 12A and the second power supply wire 12B. Therefore, in the first intermediate wiring layer 22 having the priority wiring direction same as that of the upper-layer power-supply wiring layer 12, the width in the X direction in the areas where the first via row and the second via row are formed is smaller than the width in the X direction of the areas where the first via row 123A and the second via row 123B of the example are formed. As a result, it is possible to increase the number of wiring tracks that can be arranged in the Y direction compared with the number of wiring tracks in the example. In particular, when the first via row and the second via row are formed on one straight line, via rows are formed in a number a half as large as the number of the first and second power supply wires 12A and 12B formed in the upper-layer power-supply wiring layer 1. Therefore, concerning the first intermediate wiring layer 22, there is an effect that the number of tracks occupied by the wire connecting sections 20A and 20B can be reduced to a half at the maximum and the number of wiring tracks that can be used for signal wires can be increased compared with the example shown in FIGS. 11 and 12.

In the example explained above, the two intermediate wiring layers 22 and 24 are present between the lower-layer power-supply wiring layer 11 and the upper-layer power-supply wiring layer 12. However, the present invention can be applied in the same manner when three or more intermediate wiring layers are present. In this case, in intermediate wiring layers having a priority wiring direction different from that of the upper-layer power-supply wiring layer 12, the via-position converting and connecting wires 24A and 24B only have to be formed that have the crossing-position forming sections 241 in crossing positions of an upper-layer power-supply wiring layer and a lower-layer power-supply wiring layer and in which the projecting sections 242 projecting from the crossing-position forming units 241 to between the first and second power supply wires 12A and 12B of the upper-layer power-supply wiring layer 12 are formed. The projecting sections 242 of the via-position converting and connecting wires 24A and 24B and the lower-layer power supply wires only have to be connected by vertical vias. It is desirable to form via-position converting and connecting wires in an intermediate wiring layer closest to the upper-layer power-supply wiring layer 12 among the intermediate wiring layers having the priority wiring direction different from that of the upper-layer power-supply wiring layer 12. This is because the number of wiring tracks that can be formed in the intermediate wiring layers having a priority wiring direction same as that of the upper-layer power-supply wiring layer 12 below the intermediate wiring layer increases.

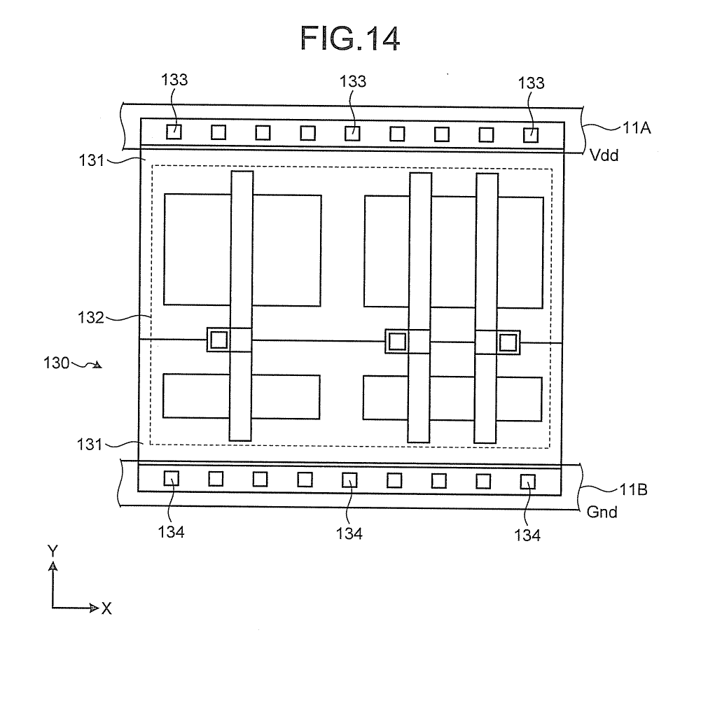

The first power supply wires 11A and the second power supply wires 11B of the lower-layer power-supply wiring layer 11 can be power supply wires of a standard cell used to form a semiconductor integrated circuit. FIG. 14 is a diagram of an example of the configuration of the standard cell. In the figure, a left to right direction of the paper surface is represented as X direction and a direction perpendicular to the X direction is represented as Y direction. In this standard cell 130, a field effect transistor 132 is formed near the center of a well region 131 of a predetermined conduction type. At one end in the Y direction of the well region 131, the first power supply wire 11A as a power supply wire for high potential (VDD) is formed to extend in the X direction. At the other end, the second power supply wire 11B as a power supply wire for ground potential (Gnd) is formed to extend in the X direction. The first and second power supply wires 11A and 11B are connected to the well region 131 via contacts 133 and 134.

Such a standard cell 130 is arranged in, for example, a layer below the lower-layer power-supply wiring layer shown in FIG. 2. Specifically, the standard cell 130 is arranged such that, when the X and Y directions of both the figures are set the same, the positions in the Y direction of the contacts 133 and 134 coincide with the positions in the Y direction of the contacts 133 and 134 of the standard cell 130 adjacent thereto. The first power supply wire 11A is formed to connect among the contacts 133 formed at a predetermined interval in the X direction of the standard cell 130, and the second power supply wire 11B is formed to connect among the contacts 134 formed at a predetermined interval in the X direction of the standard cell 130. The first power supply wires 11A that connects among the contacts 133 of such a standard cell 130, and the second power supply wires 11B that connects among the contacts 134 of such a standard cell 130 are formed in a lower-layer power-supply wiring layer. The first and second power supply wires 11A and 11B of the lower-layer power-supply wiring layer are respectively connected to the first and second power supply wires 12A and 12B of the upper-layer power-supply wiring layer via a plurality of intermediate wiring layers. In this case, the first and second power supply wires 11A and 11B and the first and second power supply wires 12A and 12B can also be connected by the wire connecting sections 20A and 20B having the structure explained above.

As explained above, according to this embodiment, in the intermediate wiring layer having the priority wiring direction different from that of the upper-layer power-supply wiring layer 12, the forming positions of the vias and the connecting wires are changed to be arranged between the first power supply wire 12A and the second power supply wire 12B in the upper-layer power-supply wiring layer 12. Therefore, in the intermediate wiring layers below the wiring layer, the forming positions in the X direction of the vias 21A and 23A and the connecting wires 22A that connect between the first power supply wires 11A and 12A and the forming positions in the X direction of the vias 21B and 23B and the connecting wires 22B that connect between the second power supply wires 11B and 12B are arrayed to overlap each other. As a result, there is an effect that, in the intermediate wiring layer having the priority wiring direction same as that of the upper-layer power-supply wiring layer 12, it is possible to increase the number of wiring tracks that can be formed compared with the number of wiring tracks.

The via-position converting and connecting wires 24A and 24B are wires formed in the intermediate wiring layer having the priority wiring direction different from that of the upper-layer power-supply wiring layer 12 to extend along the priority wiring direction of the intermediate wiring layer. Unlike Japanese Patent Application Laid-Open No. 2008-66371, the via-position converting and connecting wires 24A and 24B do not have extending sections in a non-priority wiring direction of the intermediate wiring layer. As a result, there is also an effect that, in the intermediate wiring layer in which the via-position converting and connecting wires 24A and 24B are formed, it is possible to increase the number of tracks that can be wired in the priority wiring direction compared with Japanese Patent Application Laid-Open No. 2008-66371.

As explained above, according to the embodiment of the present invention, there is an effect that, when the upper and lower power supply wires crossing each other are connected via the connecting wires formed in the intermediate wiring layer and the vias formed in the insulating films among the wiring layers, it is possible to reduce the number of wiring tracks of the signal wires occupied by the connecting wires in the intermediate wiring layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A power-supply wiring structure for a multilayer wiring comprising:
a lower-layer power-supply wiring layer including a plurality of sets of two lower-layer power supply wires of different kinds extending in a first direction;
an upper-layer power-supply wiring layer formed in a layer above the lower-layer power-supply wiring layer and including a plurality of sets of two upper-layer power supply wires of different kinds extending in a second direction;
one or more intermediate wiring layers with the first direction set as a priority wiring direction and one or more intermediate wiring layers with the second direction set as a priority wiring direction, the intermediate wiring layers being formed between the lower-layer power-supply wiring layer and the upper-layer power-supply wiring layer;
insulating films formed among the wiring layers; and
a wiring connecting section that connects the lower-layer power supply wires and the upper-layer power supply wires of the same kind via connecting wires formed in the intermediate wiring layers and vias formed to pierce through the insulating films, wherein
one intermediate wiring layer with the first direction set as the priority wiring direction among the intermediate wiring layers includes, as the connecting wires, position converting wires including crossing-position forming sections formed in crossing positions of the upper-layer power supply wires and the lower-layer power supply wires of the same kind and projecting sections projecting from the crossing-position forming sections to sides of the upper-layer power supply wires of the different kinds in the first direction, and
the wire connecting section connects between the upper-layer power supply wires and the crossing-position forming sections of the position converting wires and connects between the projecting sections of the position converting wires and the lower-layer power supply wires via the vias.

2. The power-supply wiring structure for a multilayer wiring according to claim 1, wherein the two lower-layer power supply wires and the two higher-layer power supply wires are first power supply wires that supply first potential and second power supply wires that supply second potential.

3. The power-supply wiring structure for a multilayer wiring according to claim 1, wherein positions of the vias connected to the projecting sections of the position converting wires of the different kinds are linearly arranged in the second direction.

4. The power-supply wiring structure for a multilayer wiring according to claim 1, wherein the position converting wires of the different kinds are arranged to partially overlap in the first direction.

5. The power-supply wiring structure for a multilayer wiring according to claim 1, wherein width of the connecting wires is the same as width of other wires formed in the intermediate wiring layers.

6. The power-supply wiring structure for a multilayer wiring according to claim 1, wherein the position converting wires are formed in the intermediate wiring layer in an upper most layer among the intermediate wiring layers with the first direction set as the priority wiring direction.

7. The power-supply wiring structure for a multilayer wiring according to claim 1, wherein the lower-layer power-supply wiring layer is a part of a power supply wire of a standard cell in a semiconductor integrated circuit.

8. A power-supply wiring structure for a multilayer wiring comprising:
a lower-layer power-supply wiring layer including a plurality of sets of two lower-layer power supply wires of different kinds extending in a first direction;
an upper-layer power-supply wiring layer formed in a layer above the lower-layer power-supply wiring layer and including a plurality of sets of two upper-layer power supply wires of different kinds extending in a second direction;
one or more intermediate wiring layers with the first direction set as a priority wiring direction and one or more intermediate wiring layers with the second direction set as a priority wiring direction, the intermediate wiring layers being formed between the lower-layer power-supply wiring layer and the upper-layer power-supply wiring layer;
insulating films formed among the wiring layers; and
a wiring connecting section that connects the lower-layer power supply wires and the upper-layer power supply wires of the same kind via connecting wires formed in the intermediate wiring layers and vias formed to pierce through the insulating films, wherein
one intermediate wiring layer with the first direction set as the priority wiring direction among the intermediate wiring layers includes, as the connecting wires, in the wire connecting section of one kind of two kinds of the wire connecting sections, position converting wires including crossing-position forming sections formed in crossing positions of the upper-layer power supply wires and the lower-layer power supply wires of the same kind and projecting sections projecting from the crossing-position forming sections to below the upper-layer power supply wires of the different kinds in the first direction,
the wire connecting section of the one kind connects between the upper layer wires and the crossing-position forming sections of the position converting wires and connects between the projecting sections of the position converting wires and the lower layer wires via the vias, and
the wiring connecting section of the other kind connects between the upper layer wires and the lower layer wires via the vias.

9. The power-supply wiring structure for a multilayer wiring according to claim 8, wherein the two lower-layer power supply wires and the two higher-layer power supply wires are first power supply wires that supply first potential and second power supply wires that supply second potential.

10. The power-supply wiring structure for a multilayer wiring according to claim 8, wherein positions of the vias connected to the projecting sections of the position converting wires of the different kinds are linearly arranged in the second direction.

11. The power-supply wiring structure for a multilayer wiring according to claim 8, wherein the position converting wires of the different kinds are arranged to partially overlap in the first direction.

12. The power-supply wiring structure for a multilayer wiring according to claim 8, wherein width of the connecting wires is the same as width of other wires formed in the intermediate wiring layers.

13. The power-supply wiring structure for a multilayer wiring according to claim 8, wherein the position converting wires are formed in the intermediate wiring layer in an upper most layer among the intermediate wiring layers with the first direction set as the priority wiring direction.

14. The power-supply wiring structure for a multilayer wiring according to claim 8, wherein the lower-layer power-supply wiring layer is a part of a power supply wire of a standard cell in a semiconductor integrated circuit.

15. A method of manufacturing a multilayer wiring including:
a lower-layer power-supply wiring layer including a plurality of sets of two lower-layer power supply wires of different kinds extending in a first direction;
an upper-layer power-supply wiring layer formed in a layer above the lower-layer power-supply wiring layer and including a plurality of sets of two upper-layer power supply wires of different kinds extending in a second direction;
one or more intermediate wiring layers with the first direction set as a priority wiring direction and one or more intermediate wiring layers with the second direction set as a priority wiring direction, the intermediate wiring layers being formed between the lower-layer power-supply wiring layer and the upper-layer power-supply wiring layer;
insulating films formed among the wiring layers; and
a wiring connecting section that connects between the lower-layer power supply wires and the upper-layer power supply wires of the same kind via connecting wires formed in the intermediate wiring layers and vias formed to pierce through the insulating films, the method comprising:
forming a conductive material film on the insulating film, etching the conductive material film, and forming, in one of the intermediate wiring layers with the first direction set as the priority wiring direction, as the connecting wire, a position converting wire extending in the first direction that connects between a crossing position of the lower-layer power supply wire and the upper-layer power supply wire to be formed later of a same kind and a predetermined position from the crossing position to forming positions of the upper-layer power supply wires of the different kinds;
forming, in the intermediate wiring layers below the intermediate wiring layer including the position converting wire, connecting wires in crossing positions of the lower-layer power supply wires and the position converting wire;
forming, in the insulating films below the intermediate wiring layer including the position converting wire, vias in crossing positions of the lower-layer power supply wires and the position converting wire;
forming, in the intermediate wiring layers above the intermediate wiring layer including the position converting wire, connecting wires in crossing positions of the upper-layer power supply wires and the position converting wire; and
forming, in the insulating films above the intermediate wiring layer including the position converting wire, vias in crossing positions of the upper-layer power supply wires and the position converting wire.

16. The method of manufacturing a multilayer wiring according to claim 15, wherein the forming the position converting wire includes forming the position converting wires in each of two kinds of the wire connecting sections.

17. The method of manufacturing a multilayer wiring according to claim 15, wherein the forming the position converting wire includes forming the position converting wire only in the wire connection section of one kind of two kinds of the wire connecting sections.

18. The method of manufacturing a multilayer wiring according to claim 15, wherein
the forming the connecting wires in the intermediate wiring layers below the intermediate wiring layer including the position converting wire includes linearly forming the connecting wires in the second direction, and
the forming the vias in the insulating films below the intermediate wiring layer including the position converting wire includes linearly forming the connecting wires in the second direction.

19. The method of manufacturing a multilayer wiring according to claim 15, wherein the position converting wire is formed in the intermediate wiring layer in an upper most layer among the intermediate wiring layers with the first direction set as the priority wiring direction.

20. The method of manufacturing a multilayer wiring according to claim 15, wherein the two lower-layer power supply wires and the two higher-layer power supply wires are first power supply wires that supply first potential and second power supply wires that supply second potential.
